(19) United States
(12) Patent Application Publication
(10) Pub. No.: US 2023/0420247 A1
(43) Pub. Date: Dec. 28, 2023

(54) TRANSPARENT AND HIGH-K THIN FILM PREPARED BY PULSED LASER DEPOSITION

(71) Applicant: THE UNIVERSITY OF HONG KONG, Hong Kong (CN)

(72) Inventors: Dong HUANG, Shanghai (CN); Chi Chung Francis LING, Hong Kong (CN)

(73) Assignee: THE UNIVERSITY OF HONG KONG, Hong Kong (CN)

(21) Appl. No.: 18/037,407

(22) PCT Filed: Jan. 6, 2022
(86) PCT No.: PCT/CN2022/070478

§ 371 Date: May 17, 2023

Related U.S. Application Data
(60) Provisional application No. 63/139,106, filed on Jan. 19, 2021.

(51) Int. Cl. H01L 21/02

(52) U.S. Cl. CPC H01L 21/02266; H01L 21/02189; H01L 21/02194

(57) ABSTRACT

A thin film (Ga 0.5%, Cu 8%) co-doped ZnO with high dielectric constant and high optical transmittance in the visible light range is formed via a pulse laser deposition method. The steps of the method involve installing a sapphire based substrate mounted on a sample holder into a pulse laser deposition chamber; and installing a ZnO ceramic target containing designed Ga and Cu concentrations in the chamber. Then the chamber is evacuated until the pressure achieves 5e-4 Pa., at which point the substrate is heated to about 600 degrees C. Next oxygen gas is introduced into the chamber and adjusted to a pressure of about 5 Pa. The rotation speed of the substrate holder and target holder are adjusted to about 10 r/min. Finally, the laser beam is applied to the target to ablate it sufficiently to generate a plasma of ionized atoms that are deposited on the substrate to form the film with the same composition same as the target.

This international patent application claims the benefit of U.S. Provisional patent Application No.: 63/139,106 filed on Jan. 19, 2021, the entire content of which is incorporated by reference for all purpose.

### FIELD OF THE INVENTION

The present invention relates generally to transparent and high-k thin film, and more particularly, to a thin film that can be substituted for SiO₂ in semiconductor integrated circuits.

### BACKGROUND OF THE INVENTION

Since the 1980s Si-based integrated circuits have been enormously improved. As the transistors of Si-based integrated circuits have been scaled down so as to include more transistors on a chip and increase their speed, the thickness of their dielectric layer has been reduced as well. This has led to an increase in capacitance. However, in order to keep the physical property and intact band structure of SiO₂, the lower limit of SiO₂ is around 7 Å, according to D. A. Muller (Nature, 1999), S. Tang (Applied Surface Science, 1999), J. B. Neaton (Physical Review Letters, 2000). However, it has been determined that for SiO₂ dielectric layers of 13-15 Å, the leakage current is 1-10 A/cm². As the thickness is reduced by 1 Å, the leakage current increases by 5 times. Furthermore, if the thickness is below 20 Å, some other problems occur, such as holes and element diffusion through the gate layer, exist during the fabrication process. The best way known to solve these problems is to replace the SiO₂ material with a high-k material, where the dielectric constant k is the relative permittivity of a dielectric material. In this way, the dielectric layer thickness is increased.

Currently, in industry, the common high-k dielectric used to substitute for SiO₂ in field-effect transistors is HfO₂, which has a dielectric constant of around 25, not very high. Furthermore, Hafnium (Hf) is expensive and rare. Other potential choices are Ta₂O₃, Al₂O₃, La₂O₃, ZrO₂, TiO₂. Their dielectric constant and band gap are presented in the following table:

| | SiO₂ | Ta₂O₅ | La₂O₃ | HfO₂ | ZrO₂ | TiO₂ |
|---|---|---|---|---|---|---|
| k | 3.9 | 22 | 30 | 25 | 25 | 80 |
| E_{g}/eV | 9 | 4.4 | 6 | 5.8 | 5.8 | 3.5 |

Hu et al. have reported a new donor-acceptor co-doping method for fabricating colossal dielectric ceramic rutile material structures (A³⁺_{((4-5n)/3)-δ}B⁵⁻ₙ)ₓTi₁₋ₓO₂, where A³⁺ is a trivalent positive and B⁵⁺ is a pentavalent positive ion. x is between 0 and 1. See: CA patent 2,842,963. At room temperature, this material has a dielectric constant k of greater than 10,000, and a loss of less than 0.3 over a frequency range of about 100 Hz to about 1 MHz.

### SUMMARY OF THE INVENTION

The present inventors in reviewing the work of Hu et al. hypothesized an electron-pinned defect-dipole mechanism to explain the large dielectric constant of the dielectric ceramic rutile material structures of Hu et al. In this mechanism, hopping electrons are captured and localized by designated lattice defect states (“pinning effect”) to generate gigantic defect-dipoles that result in high-performance extremely large permittivity materials. But it should be noted that in the Hu invention, the material is based on ceramic pellets (diameter: 10 mm, thickness: 1 mm) and not transparent thin film. And as indicated by Hu et al., the sample is not transparent, having a grey or dark yellow color.

Instead, the present inventors applied the donor and acceptor co-doping method to produce transparent high-k thin dielectric film. ZnO is used as the matrix because of its high optical transmittance at visible light, whereas Ga and Cu are chosen as the donor and acceptor, respectively.

According to the present invention, the (Ga, Cu) co-doped ZnO thin film is of high dielectric constant around 200, and of high optical transmittance above 85% (average) in the visible light range. In the light spectrum from 420 to 520 nm (blue light), the transparency is on average above 75%. In the light spectrum from 520 to 820 nm, the transparency is on average above 90%. These measurements are based on a thin film sample of 400 nm thickness.

Because it has a dielectric constant 8 times larger than that of HfO₂, the (Ga, Cu) co-doped ZnO film can be substituted for HfO₂ as a dielectric material during the down-scaling of transistors. With materials having low dielectric constant, the material's thickness should be reduced in the down-scaling process to improve the capacitance of dielectric layer. In this way, the leakage current is significantly improved, which deteriorates the performance of transistor. However, with materials of high dielectric constant, the thickness can be increased, so the leakage current is reduced, thereby increasing the performance of transistor. Also, because of its transparency, the material can be applied to transparent field transistors, transparent displays and transparent capacitive coupling devices, like touch sensors. ZnO is compatible because it can be easily deposited on flexible substrates. As a result, this material has good application potential in the field of wearable electronics.

### BRIEF DESCRIPTION OF THE DRAWINGS

The foregoing and other objects and advantages of the present invention will become more apparent when considered in connection with the following detailed description and appended drawings in which like designations denote like elements in the various views, and wherein:

FIG. 1A is a schematic illustration of Ga—Cu co-doped ZnO films grown on c-sapphire according to the present invention;

FIG. 1B is a schematic illustration of an arrangement used for the dielectric characterization of a sample according to the present invention;

FIG. 2 is a graphical presentation of the dielectric constant and dielectric loss of a sample according to the present invention (Ga 0.5%, Cu 8% co-doped with ZnO) as a function of the frequency; and

FIG. 3 is a graphical representation of the optical transmission spectrum of a sample according to the present invention (Ga 0.5%, Cu 8% co-doped with ZnO).

### DETAILED DESCRIPTION OF THE INVENTION

The present invention provides a transparent and high-dielectric constant (k) thin film useful as a substitute for SiO₂ or HfO₂ in semiconductor integrated circuits such as field effect transistor. The material is prepared by a pulsed laser deposition method according to the following procedure:

1. Prepare a C-plane or R-plane of a sapphire (Al₂O₃) in a size of at least 10×5 mm, as a substrate.

2. Clean the substrate by immersing it in Acetone, ethanol and deionized water, respectively, with ultrasonic cleaning for 15 minutes each.

3. Place and fix the substrate on a sample holder and then, install this arrangement in a pulse laser deposition chamber. Install a ZnO ceramic target containing the designed Ga and Cu concentration in the chamber. The composition will be fully presented later.

4. Roughly evacuate the chamber with a mechanic pump till the pressure drops to 1˜2 Pa, then open the molecular pump to further evacuate chamber until the pressure achieves 5 e-4 Pa.

5. Next, heat the substrate to 600 degrees C.

6. Open the chamber valve to introduce oxygen gas and precisely control the gas flowmeter and molecular pump valve to adjust the oxygen pressure to 5 Pa.

7. Adjust the rotation speed of the substrate holder and target holder to 10 r/min.

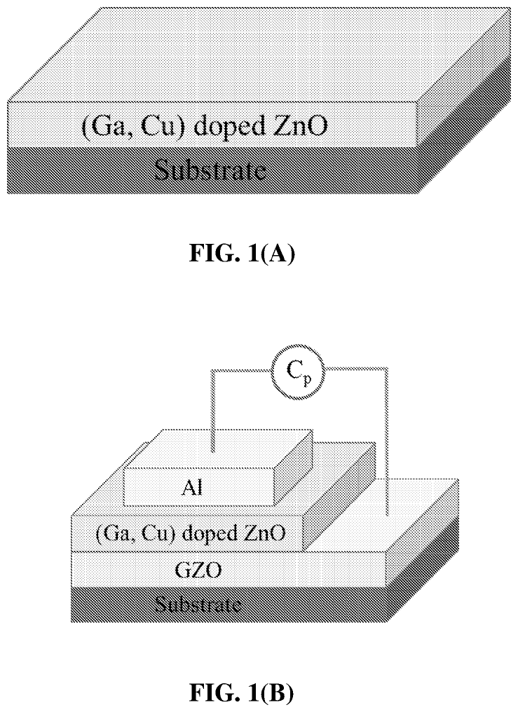

8. Open the laser machine and set the parameters at frequency=2 Hz, Energy=300 mJ and Power=0.5 W. Then, ablate the target with the incident laser beam to generate a plasma. The ionized atoms of the plasma will approach the substrate and form the film on it with the same composition as the target as shown in FIG. 1A. The deposition time is 2-4 hours depending on the designed thickness.

In an exemplary embodiment the deposition time was 4 hours and the thickness was 400 nm.

The composition of the film and also of the target is designed as set forth below in the table 1. The composition of the targets is designed as below (Ga 0.5%, Cu 2%) co-doped ZnO, (Ga 1%, Cu 2%) co-doped ZnO, (Ga 1%, Cu 4%) co-doped ZnO, (Ga 2%, Cu 4%) co-doped ZnO, (Ga 0.5%, Cu 6%) co-doped ZnO, (Ga 0.5%, Cu 8%) co-doped ZnO, (Ga 0.5%, Cu 10%) co-doped ZnO, (Ga 1%, Cu 8%) co-doped ZnO, and (Ga 2%, Cu 8%) co-doped ZnO. The schematic sample structure is shown in Table 1.

The Ga and Cu atomic compositions, dielectric constants, dielectric loss, Cu⁺:Cu²⁺ oxidation state ratios and electron concentrations for the Ga—Cu co-doped ZnO films fabricated with the ceramics containing different Ga and Cu weight compositions are as follows:

TABLE 1

| | Atomic Ratio (%) | | Dielectric property | | Cu+ and Cu2+ ratio | | |
|---|---|---|---|---|---|---|---|
| Sample | Ga | Cu | ε | tanδ | Cu+ (%) | Cu2+ (%) | n(cm⁻³) |
| ZnO-O | — | — | 7 | >10³ | — | — | 5.55e18 |
| Ga0.5-Cu2-O | 0.47 | 2.06 | 55 | 152 | ~100 | 0 | — |
| Ga1-Cu2-O | 0.94 | 2.06 | 48 | 112 | ~100 | 0 | — |
| Ga1-Cu4-O | 0.94 | 4.11 | 87 | 41 | 83.3 | 16.7 | — |
| Ga2-Cu4-O | 1.88 | 4.12 | 72 | 16 | ~100 | 0 | — |
| Ga0.5-Cu6-O | 0.47 | 6.17 | 96 | 48 | 61.9 | 38.1 | — |
| Ga0.5-Cu8-O | 0.47 | 8.22 | 199 | 0.28 | 60.3 | 39.7 | 1.93e14 |
| Ga0.5-Cu10-O | 0.47 | 10.27 | 93 | 0.73 | 48.7 | 51.3 | — |
| Ga1-Cu8-O | 0.94 | 8.22 | 98 | 0.26 | 62.0 | 38.0 | — |
| Ga2-Cu8-O | 1.87 | 8.23 | 124 | 0.56 | 79.0 | 21.0 | — |

### First Innovative Concept:

As indicated in Table 1, when the doping amount Ga is 0.5 wt %, Cu is 8 wt % and the other conditions remain, the dielectric constant is the highest and the dielectric loss is be lowest, which are 199 and 0.28, respectively. Currently, the common choice for the dielectric in the semiconductor industry is HfO₂, the dielectric constant of which is around 25. Other potential choices are Ta₂O₃, Al₂O₃, La₂O₃, ZrO₂, TiO₂. Their dielectric constant and band gap are presented in the Table 2:

TABLE 2

| | SiO₂ | Ta₂O₅ | La₂O₃ | HfO₂ | ZrO₂ | TiO₂ |
|---|---|---|---|---|---|---|
| k | 3.9 | 22 | 30 | 25 | 25 | 80 |
| E_{g}/eV | 9 | 4.4 | 6 | 5.8 | 5.8 | 3.5 |

In the present invention, the (Ga, Cu) co-doped ZnO thin film is of high dielectric constant, around 200, which is nearly 8 times than that of HfO₂, the (Ga, Cu) co-doped ZnO can substitute for the HfO₂ as a dielectric material during the down-scaling of a transistor. FIG. 1B is a schematic structure of the arrangement for determining the dielectric characterization of a sample of the present invention. On top of the Substrate there is a GZO layer with the (Ga, Cu) doped ZnO film on top. An aluminum electrode is placed on the film and a frequency source and capacitive measurement device is connected between the GZO layer and the aluminum electrode. The frequency is varied, and the capacitance is measured to determine the spectra of the dielectric property of the film according to the present invention.

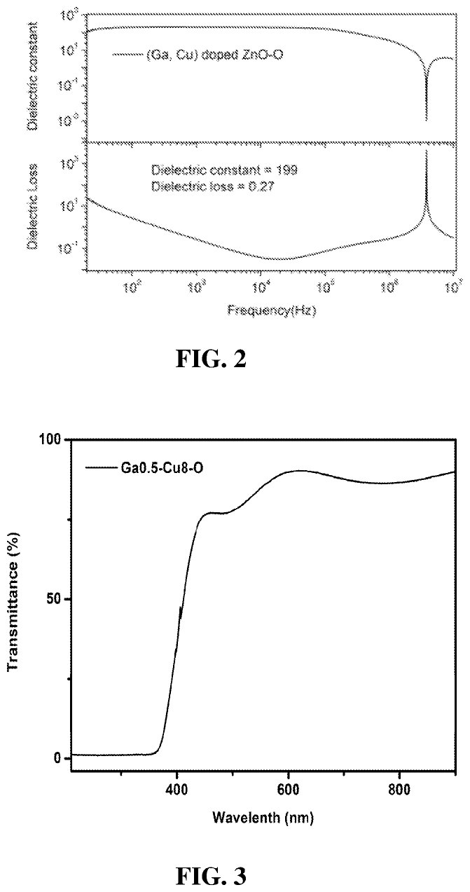

The spectra of dielectric property k versus frequency is presented in FIG. 2. It shows the frequency dependence of the dielectric constant and the dielectric loss of this sample, which for the dielectric constant is relatively stable over a wide range of frequency (100 Hz to 10⁵ Hz).

### Second Innovative Concept:

FIG. 3 shows the optical transmittance spectrum of the sample. The optical transmittance is >80% for the optical wavelength region. In the light spectrum from 420 to 520 nm (blue light), the transparency averages above 75%. In the light spectrum from 520 to 820 nm, the transparency averages above 90%. These measurements are based on z thin film sample of 400 nm thickness.

### Third Innovative Concept:

Hafnium oxide (HfO₂) is expensive and is low in abundance as a rare earth metal oxide. Zinc oxide is an ordinary oxide with a lower price and higher abundance. If the Hafnium oxide is replaced with the Zinc oxide according to the present invention in the electronics industry, the cost of the fabrication of integrated circuit products will be dramatically reduced.

According to the present invention a thin film (Ga 0.5%, Cu 8%) co-doped ZnO with high dielectric constant, around 200, and of high optical transmittance, above 85% (average) in the visible light range, is formed via the pulse laser deposition method. Its dielectric constant is 8 times than that of HfO₂, which enables the (Ga, Cu) co-doped ZnO to substitute for the HfO₂ as a dielectric material during the down-scaling of transistors. Also, the dielectric film according to the present invention has a cost that is dramatically reduced in the case of the replacement of HfO₂ with ZnO.

While the present invention has been particularly shown and described with reference to preferred embodiments thereof; it will be understood by those skilled in the art that various changes in form and details may be made therein without departing from the spirit and scope of the invention, and that the embodiments are merely illustrative of the invention, which is limited only by the appended claims. In particular, the foregoing detailed description illustrates the invention by way of example and not by way of limitation. The description enables one skilled in the art to make and use the present invention, and describes several embodiments, adaptations, variations, and method of uses of the present invention.

What is claimed is:

1. A thin film (Ga 0.5%, Cu 8%) co-doped ZnO with high dielectric constant and high optical transmittance in the visible light range formed via a pulse laser deposition method.

2. The thin film of claim 1, wherein the dielectric constant is around 200.

3. The thin film of claim 1, wherein the optical transmittance is above 85% (average) in the visible light range.

4. A method for manufacturing a thin film (Ga 0.5%, Cu 8%) co-doped ZnO, comprising the steps of:
(d) installing a sapphire based substrate mounted on a sample holder into a pulse laser deposition chamber;
(e) installing a ZnO ceramic target containing designed Ga and Cu concentrations in the chamber;
(f) evacuating the chamber until the pressure achieves 5 e-4 Pa.;
(g) heating the substrate to about 600 degrees C.;
(h) introducing oxygen gas into the chamber and adjusting it to a pressure of about 5 Pa;
(i) adjusting the rotation speed of the substrate holder and target holder to about 10 r/min;
(j) opening the laser and applying the laser beam to ablate the target sufficient to generate a plasma, whereby ionized atoms of the target approach the substrate and are deposited thereon to form the film with the same composition same as the target.

5. The method of claim 4, wherein prior to placing the substrate in the chamber it is formed as follows:
(a) prepare the C-plane or R-plane of a sapphire (Al₂O₃) as a base substrate in a size of at least 10×5 mm;
(b) clean the base substrate by immersing it in Acetone, ethanol and deionized water, respectively, with ultrasonic cleaning for 15 minutes each; and
(c) place and fix the substrate on a sample holder.

6. The method of claim 4, wherein the step of evacuating the chamber involves the steps of:
(f1) roughly evacuate the chamber with a mechanic pump till the pressure goes down to 1-2 Pa, and
(f2) then open the molecular pump to further evacuate the changer until the pressure achieves 5 e-4 Pa.

7. The method of claim 4, wherein the step of introducing oxygen involves the steps of:
(h1) opening an oxygen gas inlet valve to introduce the oxygen gas to the chamber; and
(h2) precisely controlling the oxygen gas flowmeter and molecular pump valve to adjust the oxygen pressure to 5 Pa.

8. The method of claim 4 wherein prior to the step of opening the laser, setting the laser parameters as frequency=2 Hz, Energy=300 mJ and Power=0.5 W.

9. The method of claim 4, wherein the time for the deposition of ionized atoms of the target on the substrate is about 2-4 hrs depending on the designed thickness.

10. The method of claim 9 wherein the time for deposition is about 4 hrs and the film thickness is about 400 nm.

11. The method of claim 4 wherein the composition of the target is one of (Ga 0.5%, Cu 2%) co-doped ZnO, (Ga 1%, Cu 2%) co-doped ZnO, (Ga 1%, Cu 4%) co-doped ZnO, (Ga 2%, Cu 4%) co-doped ZnO, (Ga 0.5%, Cu 6%) co-doped ZnO, (Ga 0.5%, Cu 8%) co-doped ZnO, (Ga 0.5%, Cu 10%) co-doped ZnO, (Ga 1%, Cu 8%) co-doped ZnO and (Ga 2%, Cu 8%) co-doped ZnO.

12. The thin film (Ga 0.5%, Cu 8%) co-doped ZnO of claim 1, having the composition of one of (Ga 0.5%, Cu 2%) co-doped ZnO, (Ga 1%, Cu 2%) co-doped ZnO, (Ga 1%, Cu 4%) co-doped ZnO, (Ga 2%, Cu 4%) co-doped ZnO, (Ga 0.5%, Cu 6%) co-doped ZnO, (Ga 0.5%, Cu 8%) co-doped ZnO, (Ga 0.5%, Cu 10%) co-doped ZnO, (Ga 1%, Cu 8%) co-doped ZnO and (Ga 2%, Cu 8%) co-doped ZnO.
